(19) United States
(12) Patent Application Publication
(10) Pub. No.: US 2022/0019203 A1
(43) Pub. Date: Jan. 20, 2022

(54) METHOD AND DEVICE FOR PROCESSING SEMICONDUCTOR MANUFACTURING INFORMATION

(71) Applicant: CHANGXIN MEMORY TECHNOLOGIES, INC., Hefei City (CN)

(72) Inventors: Kai YANG, Hefei (CN); Jingwei HUANG, Hefei (CN)

(21) Appl. No.: 17/385,059

(22) Filed: Jul. 26, 2021

Related U.S. Application Data
(63) Continuation of application No. PCT/CN2021/093138, filed on May 11, 2021.

(30) Foreign Application Priority Data
Jul. 16, 2020 (CN) 202010686761.2

(51) Int. Cl. G05B 19/418; G05B 23/02

(52) U.S. Cl. CPC G05B 19/41875; G05B 2219/45031; G05B 23/0235

(57) ABSTRACT

A method and a device for processing semiconductor manufacturing information and a semiconductor manufacturing information processing device are involved. The method for processing semiconductor manufacturing information includes that: acquiring manufacturing information through a Manufacturing Execution System (MES), and the manufacturing information is provided by the MES for a Statistical Process Control (SPC) system to generate check information; detecting whether the manufacturing information is matched with the check information, and in response to the manufacturing information being unmatched with the check information, outputting alerting information. According to the provided method for processing semiconductor manufacturing information, a condition that the manufacturing information is lost and not monitored may be reduced, and a process control risk may be prevented.

### CROSS-REFERENCE TO RELATED APPLICATIONS

This is a continuation of International Application No. PCT/CN2021/093138, filed on May 11, 2021, which claims priority to Chinese Patent Application No. 202010686761.2, filed on Jul. 16, 2020, and entitled “Method and Device for Processing Semiconductor Manufacturing Information”. The disclosures of International Application No. PCT/CN2021/093138 and Chinese Patent Application No. 202010686761.2 are hereby incorporated by reference in their entireties.

### TECHNICAL FIELD

The disclosure relates to the technical field of semiconductors, and particularly to a method and a device for processing semiconductor manufacturing information.

### BACKGROUND

In the semiconductor industry, each product needs to go through hundreds of processes and measurement steps from entering a factory to leaving the factory, which may contain at least over a thousand pieces of manufacturing information, and the quality of each piece of manufacturing information may affect the final quality of the product. Therefore, a Statistical Process Control (SPC) judgment is required to be performed on a large amount of manufacturing information.

However, the SPC judgment of the manufacturing information may be missed in existing processing methods. The missing SPC judgment of the manufacturing information refers to a blind spot of process control in the semiconductor industry.

It should be noted that the information disclosed in BACKGROUND is only used to strengthen the understanding to the background of the disclosure, and thus may include information that does not constitute the conventional art known to those of ordinary skill in the art.

### SUMMARY

An objective of the disclosure is to provide a method and a device for processing semiconductor manufacturing information, which may reduce a condition that manufacturing information is lost and not monitored and also prevent a process control risk.

According to an aspect of the disclosure, a method for processing semiconductor manufacturing information is provided, which may include the following operations.

Manufacturing information is acquired through a Manufacturing Execution System (MES), and the manufacturing information is provided by the MES for a Statistical Process Control (SPC) to generate check information.

Whether the manufacturing information is matched with the check information is detected, and in response to the manufacturing information being unmatched with the check information, alerting information is output.

According to another aspect of the disclosure, a device for processing semiconductor manufacturing information is provided, which may include an MES, a process control system, and an alerting system.

The MES may be configured to acquire manufacturing information.

The process control system may be connected with the MES and configured to generate check information according to the manufacturing information acquired by the MES.

The alerting system may be connected with the MES and the process control system and configured to detect whether the manufacturing information is matched with the check information, and in response to the manufacturing information being unmatched with the check information, output alerting information.

It is to be understood that the above general description and the following detailed description are only exemplary and explanatory, which will be not intended to limit the disclosure.

### BRIEF DESCRIPTION OF THE DRAWINGS

The accompanying drawings, which are incorporated in and constitute a part of the specification, illustrate embodiments consistent with the disclosure and, together with the specification, serve to illustrate the principle of the disclosure. It is apparent that the drawings in the following description are only some embodiments of the disclosure, and those of ordinary skill in the art may further obtain other drawings according to these drawings without creative work.

FIG. 1 is a flowchart of a method for processing semiconductor manufacturing information according to an embodiment of the disclosure.

FIG. 2 is a schematic diagram of a device for processing semiconductor manufacturing information according to an embodiment of the disclosure.

FIG. 3 is a schematic diagram of an electronic device according to an embodiment of the disclosure.

### DETAILED DESCRIPTION

Exemplary embodiments will now be described more comprehensively with reference to the drawings. However, the exemplary embodiments may be implemented in various forms, and should not be understood to be limited to examples elaborated herein. Instead, the embodiments may be provided to make the disclosure more comprehensive and complete, and to communicate ideas of the exemplary embodiments to those skilled in the art. The described features, structures, or characteristics may be combined in one or more embodiments in any appropriate manner In the following description, many specific details are provided to fully understand the embodiments of the disclosure. However, it will be realized by those skilled in the art that the technical solutions of the disclosure may be put into practice with one or more of the specific details omitted, or other methods, devices, steps, etc., may be used. In other cases, the technical solutions of the disclosure will not be shown or described in detail to avoid distraction to obscure each aspect of the disclosure.

In addition, some block diagrams shown in the drawings illustrate functional entities, which may not need to correspond to physically or logically independent entities. These functional entities may be implemented in a software form, or these functional entities are implemented in one or more hardware modules or integrated circuits, or these functional entities are implemented in different networks, and/or, different processor devices, and/or, different microcontroller devices. Terms such as “a/an”, “one”, “the”, and “said” are used to represent existence of one or more elements/components, etc. Terms “include” and “have” are used to represent open inclusion, and refer to that another element/component, etc., may exist besides the listed elements/components, etc. Terms such as “first”, “second”, “third”, are used not to limit the numbers of objects thereof but only as marks.

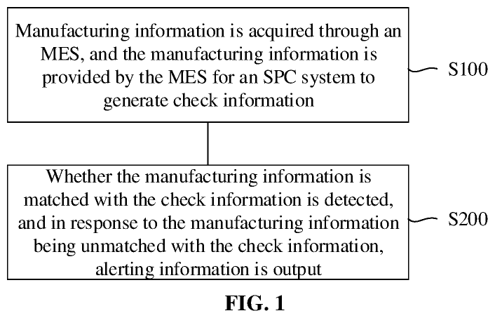

Firstly, an exemplary embodiment provides a method for processing semiconductor manufacturing information. As shown in FIG. 1, the method for processing semiconductor manufacturing information includes the following operations of S100 and S200.

In S100, manufacturing information is acquired through a Manufacturing Execution System (MES), and the manufacturing information is provided by the MES for a Statistical Process Control (SPC) system to generate check information.

In S200, whether the manufacturing information is matched with the check information is detected, and in response to the manufacturing information being unmatched with the check information, alerting information is output.

According to the method for processing semiconductor manufacturing information provided in the disclosure, the manufacturing information may be acquired through the MES, and the check information may be generated by the SPC system; then whether the manufacturing information is matched with the check information may be detected, and in response to the manufacturing information being unmatched with the check information, the alerting information may be output to remind a corresponding engineer. Therefore, the manufacturing information being lost and not monitored can be reduced, and a process control risk can be prevented.

Each step of the method for processing semiconductor manufacturing information in the exemplary embodiment will further be described below.

In S100, the manufacturing information is acquired through the MES, and the manufacturing information is provided by the MES for the SPC system to generate the check information.

Specifically, after acquiring the manufacturing information through the MES and before the manufacturing information being provided by the MES for the SPC system to generate the check information, the processing method may further include: performing an information filtering process, the information filtering process being configured to pre-filter manufacturing information that does not have to be provided for the SPC system in the MES.

A filtering logic may be preset, the manufacturing information that does not have to be provided for the SPC system in the MES may be pre-filtered according to the preset filtering logic. After the manufacturing information that does not have to be provided for the SPC system in the MES being pre-filtered according to the preset filtering logic, other manufacturing information may be provided for the SPC system to generate the check information, further to reduce false alerting.

Exemplarily, the operation of presetting the filtering logic may be set under the following conditions that do not have to be detected by the SPC system: 1) for product groups that do not have to be detected by the SPC system: for example, not all of newly developed products are required to be detected by the SPC system; 2) for sub routes that do not have to be detected by the SPC system: measurement parameters are not required to be detected by the SPC system, and are only provided for engineers as references; 3) for measurement sites (Measure Op No.) that do not have to be detected by the SPC system: part of the measurement sites are not required to be detected by the SPC system, and only received values are provided for the engineers as references; and 4) for measurement parameters (Direct Current (DC) Item) that do not have to be detected by the SPC system: part of the measurement parameters are not required to be detected by the SPC system, and only received values are provided for the engineers as references. The filtering logic can be set by those skilled in the art as practically requirements, and no limits are made thereto in the disclosure.

In S200, whether the manufacturing information is matched with the check information is detected, and in response to the manufacturing information being unmatched with the check information, the alerting information is output.

Specifically, whether the manufacturing information is matched with the check information may be detected at a time interval. When the manufacturing information is acquired once through the MES at a preset time interval, the manufacturing information acquired in each period and data such as a product group that the manufacturing information belongs to, a production route (route Identity (ID)), a process site (Op No), a measurement type (DC ID), a measurement parameter (DC Item), an Equipment (EQP) ID, and a chamber ID therein may be comprehensively compared with the check information (i.e., the group (Group) and the control chart (Chart) being set in the SPC system) one by one. In response to the manufacturing information being unmatched with the check information, the alerting information may be output. The Group may be defined as a certain process site, and the Chart may be defined as a specific parameter required to be measured after the completion of the process site, as well as a specification line and a control line, etc., of the parameter. There may be multiple Charts under a Group, to monitor different parameters.

A complete set of automatic decision logics may be established and constructed into a periodic check monitor program (Watchdog) to scan historical data of all lots in the MES every half an hour, so as to find the manufacturing information as well as a product group that the manufacturing information belongs to, a production route (route ID), a process site (Op No), a measurement type (DC ID), a measurement parameter (DC Item), an EQP ID, and a chamber ID therein. That is, whether the manufacturing information is matched with the check information may be detected at a time interval. The time interval may be preset as 10 minutes, 40 minutes, 60 minutes, etc. No limits are made thereto in the disclosure.

Specifically, the manufacturing information and the check information may be classified respectively level by level according to a same classification rule. A level-by-level comparison may be performed on the manufacturing information with the check information to detect whether the manufacturing information and the check information of the same level are matched. In response to the manufacturing information and the check information of a certain level being unmatched, the level-by-level comparison may be stopped. Based on the level-by-level comparison, the manufacturing information being unmatched with the check information can found timely, and a level where they are unmatched can be detected, so as to rapidly determine the unmatched manufacturing information.

The alerting information may include alerting information of multiple levels. Alerting information of each level may correspond to a respective level of the manufacturing information and the check information. In response to the manufacturing information and the check information of a certain level being unmatched, the alerting information of a level corresponding the manufacturing information and the check information is output, so that the engineer can deal with the unmatched manufacturing information timely and accurately.

Exemplarily, the manufacturing information may include first-level manufacturing information, second-level manufacturing information, and third-level manufacturing information. The check information may include first-level check information, second-level check information, and third-level check information. The alerting information may include first-level alerting information, second-level alerting information, and third-level alerting information. The level-by-level comparison may be performed on the first-level manufacturing information with the first-level check information, the level-by-level comparison may be performed on the second-level manufacturing information with the second-level check information, and the level-by-level comparison may be performed on the third-level manufacturing information with the third-level check information.

In response to the first-level manufacturing information being unmatched with the first-level check information, the first-level alerting information may be output. In response to the first-level manufacturing information being matched with the first-level check information, the second-level manufacturing information may be compared with the second-level check information. In response to the second-level manufacturing information being unmatched with the second-level check information, the second-level alerting information may be output. In response to the second-level manufacturing information being matched with the second-level check information, the third-level manufacturing information may be compared with the third-level check information. In response to the third-level manufacturing information being unmatched with the third-level check information, the third-level alerting information may be output. In response to the third-level manufacturing information being matched with the third-level check information, it is detected there is not a condition that the manufacturing information is lost or not monitored.

In a three-layer detection logic provided in the disclosure, a parameter detected by a first-layer logic may at least include a process site, a parameter detected by a second-layer logic may at least include a measurement type, and a parameter detected by a third-layer logic may at least include a measured value.

Exemplarily, as shown in Table 1, the first-level check information may include a product group (P_Group) and a process site (Oper No), and the first-level manufacturing information may be the manufacturing information about the product group and the process site. The first-level manufacturing information may be compared with the first-level check information; if the data is matched, the check succeeds, and if the data is unmatched, “un-defined SPC chart” is detected, and the first-level alerting information “No chart” is output.

The second-level check information may include a measurement type (DC Def, defined as a certain site and a certain measurement type), a measurement parameter (DC Item), and a EQP ID. The second-level manufacturing information may be the manufacturing information about the measurement type, the measurement parameter, and the EQP ID. The second-level manufacturing information may be compared with the second-level check information; if the data is matched, the check succeeds, and if the data is unmatched, “Chart setting error” is detected, and the second-level alerting information “Wrong Chart” is output.

The third-level check information may include a lot ID, a wafer ID, time, and a measured value (Value). The third-level manufacturing information may be manufacturing information about the lot ID, the wafer ID, the time, and the measured value. The third-level manufacturing information may be compared with the third-level check information; if the data is matched, the check succeeds, and if the data is unmatched, “system communication error” is detected, and the third-level alerting information “System Error” is output.

Based on the analogy of the multiple-level detection, unnecessary data analysis may be effectively reduced, and the types of problems may be detected more accurately.

TABLE 1

| | P_Group | Oper No | DC | Def DC Item | EQ ID | Lot ID | Wafer ID | Time | Value |
|---|---|---|---|---|---|---|---|---|---|
| TEST LotInfo | AAAA | XXXX.XXX | ababab | CD_1 | AAAA101-B | AA111****.01 | AA111****.02 | 6/11 20:32 | 202.69 |
| SPC system | AAAA | XXXX.XXX | | | | | | | |
| Judge1 | ◯ | ◯ | | | | | | | |
| SPC system | | | ababab | CD_1 | AAAA101-B | | | | |
| Judge2 | | | ◯ | ◯ | ◯ | | | | |
| SPC system | | | | | | AA111****.01 | AA111****.02 | 6/11 20:32 | 202.69 |
| Judge3 | | | | | | ◯ | ◯ | ◯ | ◯ |

In the table 1, TEST Lot Info refers to test lot information, SPC system refers to the SPC system, and Judge refers to detection.

It should be noted that, in the disclosure, the operation of classifying the manufacturing information and the check information respectively level by level according to the same classification rule, may not be limited to the abovementioned three levels, and those skilled in the art may classify the information into two levels, four levels, or more levels for the level-by-level comparison. It should be understood that, if there are more levels in the classification, detection of more levels may be performed to further effectively reduce unnecessary data analysis and accurately detect the problem type. In addition, an attribute corresponding to the manufacturing information of each level is also not limited, and may be set by those skilled according to a practical condition. No limits are made thereto in the disclosure.

In addition, the method for processing semiconductor manufacturing information provided in the disclosure may further include: executing a preset processing step according to the alerting information until the manufacturing information is matched with the check information.

Exemplarily, when the P_Group and the Oper No are matched, but no corresponding SPC charts are found for all measurement parameters, it is detected that the engineer misses the parameter, and a mail may be sent to remind the engineer of the department to timely construct a chart for the parameter. When one or more of the DC Def, the DC Item, and the EQP ID is not matched, it is detected that the engineer constructs the chart for the parameter wrongly, and a mail may be sent to remind the engineer of the department to timely amend the chart. When the P_Group, the Oper No, the DC Def, the DC Item, the EQP ID, etc., may all be matched but the measured value (Value) is unmatched, it indicates a system communication error, and a mail may be sent to notify the engineer to timely check abnormalities of the MES system and the SPC system until the manufacturing information and the check information of each level are matched respectively.

In addition, although each step of the method in the disclosure is described according to a specific sequence in the drawings, it is not required or implied that these steps have to be executed according to the specific sequence, or all the shown steps have to be executed to achieve an expected result. Additionally or alternatively, some steps may be omitted, multiple steps may be combined into one step for execution, and/or one step may be split into multiple steps for execution, etc.

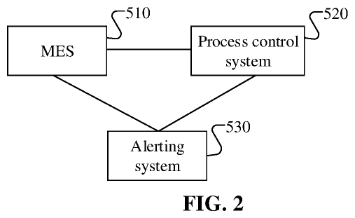

The disclosure also provides a device for processing semiconductor manufacturing information. As shown in FIG. 2, the device for processing semiconductor manufacturing information includes a Manufacturing Execution System (MES) 510, a process control system 520, and an alerting system 530. The MES 510 is configured to acquire manufacturing information. The process control system 520 is connected with the MES 510 and configured to generate check information according to the manufacturing information acquired by the MES 510. The alerting system 530 is connected with the MES 510 and the process control system 520, and configured to detect whether the manufacturing information is matched with the check information, and in response to the manufacturing information being unmatched with the check information, output alerting information.

According to the device for processing semiconductor manufacturing information provided in the disclosure, the manufacturing information is acquired through the MES, the check information is generated by the SPC system, and then the alerting system detects whether the manufacturing information is matched with the check information; and in response to the manufacturing information being unmatched with the check information, the alerting information is output to remind a corresponding engineer. Therefore, the manufacturing information being lost and not monitored can be reduced, and a process control risk can be prevented.

The alerting system 530 may include a failure detection unit. The failure detection unit may be connected with the MES 510 and the process control system 520. The failure detection unit may be configured to detect a condition that the manufacturing information is unmatched with the check information, determine a failure level corresponding to the manufacturing information and the check information, and output the alerting information corresponding to the manufacturing information and the check information. The failure level may be specifically determined with reference to the failure level in the method for processing semiconductor manufacturing information.

In addition, the device may further include a failure clearing system, connected with the alerting system 530. The failure clearing system is configured to execute a processing step corresponding to the alerting information until failures are cleared. The specific processing step may refer to the failure clearing method in the method for processing semiconductor manufacturing information.

Since each functional system of the device for processing semiconductor manufacturing information of the exemplary embodiment of the disclosure corresponds to the steps of the exemplary embodiment of the method for processing semiconductor manufacturing information, undisclosed details in the device embodiments of the disclosure refer to the embodiments of the method for processing semiconductor manufacturing information of the disclosure, and will not be elaborated here.

It should be noted that, although a plurality of systems of the device for action execution are mentioned in the above detailed descriptions, such division is not mandatory. In practice, features and functions of two or more systems described above may be embodied in one system according to the embodiments of the disclosure. Conversely, the features and functions of one system described above may further be divided into multiple systems for embodiment.

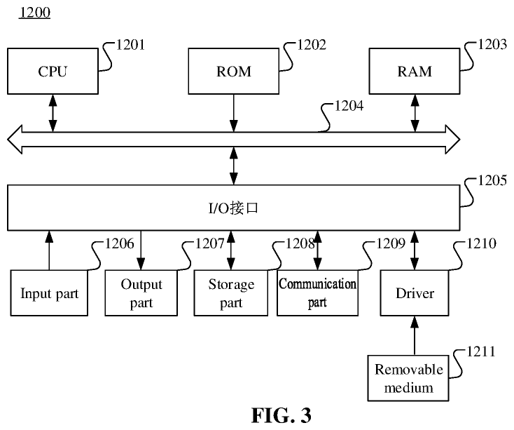

Referring to FIG. 3, FIG. 3 shows a structure diagram of a computer system 1200 of an electronic device applied to implement the embodiments of the disclosure. The computer system 1200 of the electronic device in FIG. 3 is only an example, which should not cause any limit to the functions and scope of the embodiments of the disclosure.

As shown in FIG. 3, the computer system 1200 may include a Central Processing Unit (CPU) 1201 that may execute various appropriate actions and processes according to a program stored in a Read-Only Memory (ROM) 1202 or a program loaded from a storage part 1208 to a Random Access Memory (RAM) 1203. Various programs and data needed by operations of the system may also be stored in the RAM 1203. The CPU 1201, the ROM 1202, and the RAM 1203 may be connected with one another through a bus 1204. An Input/Output (I/O) interface 1205 may also be connected to the bus 1204.

The following components may be connected to the I/O interface 1205: an input part 1206 including a keyboard, a mouse, etc., an output part 1207 including a Cathode-Ray Tube (CRT), a Liquid Crystal Display (LCD), a speaker, etc., a storage part 1208 including a hard disk, etc., and a communication part 1209 including a Local Area Network (LAN) card and a network interface card of a modem, etc. The communication part 1209 may execute communication processes through a network such as the Internet. A driver 1210 is also connected to the I/O interface 1205 as required. A removable medium 1211, for example, a magnetic disk, an optical disk, a magneto-optical disk and a semiconductor memory, may be installed on the driver 1210 as required, such that a computer program read therefrom may be installed in the storage part 1208 as required.

Particularly, the processes described above with reference to the flowcharts may be implemented as computer software programs according to the embodiments of the disclosure. For example, the embodiments of the disclosure may include a computer program product, which may include a computer program born in a computer-readable medium. And the computer program may include a program code configured to execute the method shown in the flowchart. In such embodiments, the computer program may be downloaded from the network and installed through the communication part 1209 and/or installed from the removable medium 1211. The computer program may be executed by the CPU 1201 to execute the function defined in the system of the disclosure.

It should be noted that the computer-readable medium shown in the disclosure may be a computer-readable signal medium or a computer-readable storage medium, or any combination of the computer-readable signal medium and the computer-readable storage medium. The computer-readable storage medium may be, but not limited to, for example, a system, a device, or an apparatus which may be based on electricity, magnetism, light, electromagnetism, infrared light, or semiconductor, or any combination of thereof. More specific examples of the computer-readable storage medium may include, but not limited to, an electrical connector with one or more wires, a portable computer disk, a hard disk, a RAM, a ROM, an Erasable Programmable ROM (EPROM) (or a flash memory), an optical fiber, a portable Compact Disc Read-Only Memory (CD-ROM), an optical storage device, a magnetic storage device, or any proper combination thereof. In the disclosure, the computer-readable storage medium may be any physical medium including or storing a program, and the program may be used by or in combination with an instruction execution system, an instruction execution device, or an instruction execution apparatus. In the disclosure, the computer-readable signal medium may include a data signal in a baseband or propagated as part of a carrier, a computer-readable program code being born therein. A plurality of forms may be adopted for the propagated data signal, including, but not limited to, an electromagnetic signal, an optical signal, or any proper combination. The computer-readable signal medium may also be any computer-readable medium except the computer-readable storage medium, and the computer-readable medium may send, propagate, or transmit a program configured to be used by or in combination with the instruction execution system, the instruction execution device, or the instruction execution apparatus. The program code in the computer-readable medium may be transmitted with any proper medium, including, but not limited to, radio, an electric wire, an optical cable, Radio Frequency (RF), etc. or any proper combination thereof.

The flowcharts and block diagrams in the drawings illustrate probably implemented system architectures, functions, and operations of the system, the method, and the computer program product according to various embodiments of the disclosure. On this aspect, each block in the flowcharts or the block diagrams may represent part of a module, a program segment, or a code. And the part of the module, the program segment, or the code may include one or more executable instructions configured to realize a specified logical function. It is also to be noted that, in some alternative implementations, the functions marked in the blocks may also be realized in a sequence different from those marked in the drawings. For example, two continuous blocks may actually be executed substantially in parallel, and they may also be executed in a reverse sequence sometimes, depending on the involved functions. It is further to be noted that each block in the block diagrams and the flowcharts and a combination of the blocks in the block diagrams and the flowcharts may be implemented by a dedicated hardware-based system configured to execute a specified function or a specified operation, or may be implemented by a combination of a special hardware and a computer instruction.

The system described in the embodiments of the disclosure may be implemented by software or by hardware. The described system may also be set in a processor. The names of the systems do not constitute any limit to the systems under certain circumstances.

As another aspect, the disclosure also provides a computer-readable medium. The computer-readable medium may be included in the electronic device described in the abovementioned embodiments, or may exist independently and not be assembled in the electronic device. The computer-readable medium bears one or more programs. When the one or more programs are executed by the electronic device, the electronic device may implement the method for processing semiconductor manufacturing information as described in the abovementioned embodiments.

For example, the electronic device may implement the following operations of S100 and S200 shown in FIG. 1. In S100, manufacturing information is acquired through an MES, and the manufacturing information is provided by the MES for an SPC system to generate check information. In S200, whether the manufacturing information is matched with the check information is detected, and in response to the manufacturing information being unmatched with the check information, alerting information is output.

Based on the above descriptions about the embodiments, it is easily understood by those skilled in the art that the exemplary implementations described here may be implemented by software, or may be implemented by combining the software and necessary hardware. Therefore, the technical solution according to the embodiments of the disclosure may be embodied in form of a software product. And the software product may be stored in a non-volatile storage medium (which may be a CD-ROM, a U disk, a mobile hard disk, etc.) or a network, including a plurality of instructions enabling a computing device (which may be a personal computer, a server, a touch terminal, a network device, etc.) to execute the method according to the embodiments of the disclosure.

An objective of the disclosure is to provide a method and a device for processing semiconductor manufacturing information, which may reduce a condition that manufacturing information is lost and not monitored and also prevent a process control risk.

According to an aspect of the disclosure, a method for processing semiconductor manufacturing information is provided, which may include the following operations.

Manufacturing information is acquired through a Manufacturing Execution System (MES), and the manufacturing information is provided by the MES for a Statistical Process Control (SPC) to generate check information.

Whether the manufacturing information is matched with the check information is detected, and in response to the manufacturing information being unmatched with the check information, alerting information is output.

In an exemplary embodiment of the disclosure, after acquiring the manufacturing information through the MES and before the manufacturing information being provided by the MES for the SPC system to generate the check information, the method may further include the following operation.

An information filtering process may be performed, the information filtering process being configured to pre-filter manufacturing information that does not have to be provided for the SPC system in the MES.

In an exemplary embodiment of the disclosure, the operation of detecting whether the manufacturing information is matched with the checking information may include the following operations.

The manufacturing information and the check information may be classified respectively level by level according to a same classification rule.

A level-by-level comparison may be performed on the manufacturing information with the check information to detect whether the manufacturing information and the check information of a same level are matched.

In response to the manufacturing information and the check information of a certain level being unmatched, the level-by-level comparison may be stopped.

In an exemplary embodiment of the disclosure, the alerting information may include alerting information of multiple levels, alerting information of each level may correspond to a respective level of the manufacturing information and the check information, and in response to the manufacturing information and the check information of the certain level being unmatched, the alerting information of a level corresponding to the manufacturing information and the check information may be output.

In an exemplary embodiment of the disclosure, the manufacturing information may include first-level manufacturing information, second-level manufacturing information, and third-level manufacturing information, the check information may include first-level check information, second-level check information, and third-level check information, and the alerting information may include first-level alerting information, second-level alerting information, and third-level alerting information.

The level-by-level comparison may be performed on the first-level manufacturing information and the first-level check information, the level-by-level comparison may be performed on the second-level manufacturing information with the second-level check information, and the level-by-level comparison may also be performed on the third-level manufacturing information with the third-level check information. In response to the first-level manufacturing information being unmatched with the first-level check information, the first-level alerting information may be output. In response to the second-level manufacturing information being unmatched with the second-level check information, the second-level alerting information may be output. In response to the third-level manufacturing information being unmatched with the third-level check information, the third-level alerting information may be output.

In an exemplary embodiment of the disclosure, the method may further include the following operation.

A preset processing step may be executed according to the alerting information until the manufacturing information is matched with the check information.

In an exemplary embodiment of the disclosure, the operation of detecting that whether the manufacturing information is matched with the check information may include the following operation.

A time interval may be preset, and whether the manufacturing information is matched with the check information may be detected at the time interval.

According to another aspect of the disclosure, a device for processing semiconductor manufacturing information is provided, which may include an MES, a process control system, and an alerting system.

The MES may be configured to acquire manufacturing information.

The process control system may be connected with the MES and configured to generate check information according to the manufacturing information acquired by the MES.

The alerting system may be connected with the MES and the process control system and configured to detect whether the manufacturing information is matched with the check information, and in response to the manufacturing information being unmatched with the check information, output alerting information.

In an exemplary embodiment of the disclosure, the alerting system may include a failure detection unit, and the failure detection unit may be configured to detect a condition that the manufacturing information is unmatched with the check information, determine a failure level corresponding to the manufacturing information and the check information, and output alerting information corresponding to the manufacturing information and the check information.

In an exemplary embodiment of the disclosure, the device may further include a failure clearing system, which may be connected with the alerting system, and the failure clearing system may be configured to execute a processing step corresponding to the alerting information until failures are cleared.

According to the method for processing semiconductor manufacturing information provided in the disclosure, the manufacturing information is acquired through the MES, the check information is generated by the SPC system, and then whether the manufacturing information is matched with the check information is detected, and in response to the manufacturing information being unmatched with the check information, the alerting information is output to remind a corresponding engineer. Therefore, the manufacturing information being lost and not monitored can be reduced, and a process control risk can be prevented.

Those skilled in the art will be easy to think of other embodiments of the present disclosure after considering the specification and practicing the disclosure herein. The disclosure is intended to cover any variations, uses or adaptations of the disclosure, and these variations, uses or adaptations follow the general principles of the disclosure, and include common general knowledge or conventional technical means in the technical field that are not disclosed in the disclosure. The specification and the embodiments are only regard as exemplary, and the practical scope and spirit of the disclosure are indicated by the appended claims.

It should be understood that the disclosure is not limited to the precise structures described above and shown in the drawings, and various modifications and variations may be made without departing from the scope thereof. The scope of the disclosure is only defined by the appended claims.

1. A method for processing semiconductor manufacturing information, comprising:
acquiring manufacturing information through a Manufacturing Execution System (MES), wherein the manufacturing information is provided by the MES for a Statistical Process Control (SPC) system to generate check information; and
detecting whether the manufacturing information is matched with the check information; and in response to the manufacturing information being unmatched with the check information, outputting alerting information.

2. The method of claim 1, after acquiring the manufacturing information through the MES and before the manufacturing information being provided by the MES for the SPC system to generate the check information, the method further comprising:
performing an information filtering process, the information filtering process being configured to pre-filter manufacturing information that does not have to be provided for the SPC system in the MES.

3. The method of claim 1, wherein detecting whether the manufacturing information is matched with the check information comprises:
classifying the manufacturing information and the check information respectively level by level according to a same classification rule;
performing a level-by-level comparison on the manufacturing information with the check information to detect whether the manufacturing information and the check information of a same level are matched; and
in response to the manufacturing information and the check information of a certain level being unmatched, stopping the level-by-level comparison.

4. The method of claim 3, wherein the alerting information comprises alerting information of multiple levels, alerting information of each level corresponds to a respective level of the manufacturing information and the check information; and
in response to the manufacturing information and the check information of the certain level being unmatched, outputting alerting information of a level corresponding to the manufacturing information and the check information.

5. The method of claim 4, wherein the manufacturing information comprises first-level manufacturing information, second-level manufacturing information, and third-level manufacturing information, the check information comprises first-level check information, second-level check information, and third-level check information, and the alerting information comprises first-level alerting information, second-level alerting information, and third-level alerting information; and
wherein performing the level-by-level comparison on the manufacturing information with the check information to detect whether the manufacturing information and the check information of the same level are matched comprises:
performing the level-by-level comparison on the first-level manufacturing information with the first-level checking information, performing the level-by-level comparison on the second-level manufacturing information with the second-level checking information, and performing the level-by-level comparison on the third-level manufacturing information with the third-level checking information;
in response to the first-level manufacturing information being unmatched with the first-level check information, outputting the first-level alerting information;
in response to the second-level manufacturing information being unmatched with the second-level check information, outputting the second-level alerting information; and
in response to the third-level manufacturing information being unmatched with the third-level check information, outputting the third-level alerting information.

6. The method of claim 1, further comprising:
executing a preset processing step according to the alerting information until the manufacturing information is matched with the check information.

7. The method of claim 1, wherein detecting whether the manufacturing information is matched with the check information comprises:
presetting a time interval, and detecting whether the manufacturing information is matched with the check information at the time interval.

8. A device for processing semiconductor manufacturing information, comprising:
a Manufacturing Execution System (MES), configured to acquire manufacturing information;
a process control system, connected with the MES, and configured to generate check information according to the manufacturing information acquired by the MES; and
an alerting system, connected with the MES and the process control system, and configured to detect whether the manufacturing information is matched with the check information, and in response to the manufacturing information being unmatched with the check information, output alerting information.

9. The device of claim 8, wherein the alerting system comprises a failure detection unit, wherein the failure detection unit is configured to detect a condition that the manufacturing information is unmatched with the check information, determine a failure level corresponding to the manufacturing information and the check information, and output alerting information corresponding to the manufacturing information and the check information.

10. The device of claim 8, further comprising a failure clearing system, connected with the alerting system, wherein the failure clearing system is configured to execute a processing step corresponding to the alerting information until failures are cleared.
